(19) United States
(12) Patent Application Publication
(10) Pub. No.: US 2022/0368310 A1
(43) Pub. Date: Nov. 17, 2022

(54) FILM PIEZOELECTRIC ACOUSTIC WAVE FILTER AND FABRICATION METHOD THEREOF

(71) Applicant: Ningbo Semiconductor International Corporation, Ningbo (CN)

(72) Inventors: Hailong LUO, Ningbo (CN); Wei LI, Ningbo (CN)

(21) Appl. No.: 17/871,644

(22) Filed: Jul. 22, 2022

Related U.S. Application Data
(63) Continuation of application No. PCT/CN2020/142245, filed on Dec. 31, 2020.

(30) Foreign Application Priority Data
Jan. 22, 2020 (CN) 202010075557.7
Mar. 31, 2020 (CN) 202010245425.4

(51) Int. Cl. H03H 9/54; H03H 9/205; H03H 3/02; H03H 9/13

(52) U.S. Cl. CPC H03H 9/54; H03H 9/205; H03H 3/02; H03H 9/13

(57) ABSTRACT

The present disclosure provides a film piezoelectric acoustic wave filter and a fabrication method. The film piezoelectric acoustic wave filter includes a first substrate; a plurality of acoustic wave resonator units disposed on the first substrate, where each acoustic wave resonator unit includes a piezoelectric induction plate, and a first electrode and a second electrode which are opposite to each other for applying a voltage to the piezoelectric induction plate; and further includes a capping layer on the first substrate, where the capping layer includes a plurality of sub-caps, a sub-cap of the plurality of sub-caps surrounds an acoustic wave resonator unit of the plurality of acoustic wave resonator units to form a first cavity between the acoustic wave resonator unit and the sub-cap, and a separation portion is disposed between adjacent sub-caps to isolate adjacent first cavities.

### CROSS-REFERENCE TO RELATED APPLICATIONS

This application is a continuation application of PCT Patent Application No. PCT/CN2020/142245, filed on Dec. 31, 2020, which claims priority to Chinese patent application No. 202010075557.7, filed on Jan. 22, 2020; and No. 202010245425.4, filed on Mar. 31, 2020, the entirety of all of which is incorporated herein by reference.

### FIELD OF THE DISCLOSURE

The present disclosure generally relates to the field of semiconductor device manufacturing, and more particularly, relates to a film piezoelectric acoustic wave filter and its fabrication method.

### BACKGROUND

With the development of wireless communication technology, conventional single-band single-standard equipment can no longer meet diverse requirements of communication systems. Currently, communication systems have developed toward multiple bands, which requires that communication terminals can accept various frequency bands to meet requirements of different communication service providers and different regions.

RF (radio frequency) filters are commonly used to pass or block specific frequencies or bands of RF signals. In order to meet the development needs of wireless communication technology, the RF filters used in communication terminals may need to meet technical requirements of multiple-band and multiple-standard communication. Meanwhile, the RF filters in the communication terminals may need to be constantly developed toward miniaturization and integration, and one or more RF filters may be configured in each frequency band.

The most important indicators of the RF filters may include quality factor Q and insertion loss. With the frequency difference between different frequency bands getting smaller, the RF filters may need to have high selectivity, letting in-band signals pass and blocking out-of-band signals. The larger the Q value is, the narrower the passband bandwidth of the RF filter can be achieved, thereby achieving desirable selectivity.

In the fabrication process of a resonator, a cavity may need to be formed above an acoustic transducer in the resonator, so that the acoustic wave in the resonator may propagate without interference, and the performance and function of the filter can meet requirements. At present, resonator packaging may be mainly implemented through a packaging process, and the cavity may be formed simultaneously. The cavity may accommodate multiple acoustic transducers simultaneously. For example, the resonator packaging may be mainly implemented through metal over cap technology, chip sized SAW (surface acoustic wave) package (CSSP) technology or die sized SAW package (DSSP) technology, and the like. However, the complexity of the packaging process may be high, and the process reliability may be low.

Taking the metal over cap technology as an example, in the metal over cap technology, a metal cover may be fixed on a substrate, so that the metal cover and the substrate may form a cavity, and the cavity may be configured for accommodating the acoustic transducer. The metal cover may be normally fixed on the substrate by a manner of dispensing or tin plating. When the dispensing manner is used, the adhesive used in the dispensing process may be easy to flow downstream into the cavity before solidification, thereby affecting the acoustic transducer. When the tin plating manner is used, during a reflow soldering process, melted tin may also easily flow downstream into the cavity. Both above cases are likely to cause the performance of the resonator to fail. Moreover, above-mentioned methods may have relatively high requirements on the flatness of the substrate and the metal cover, the bonding force between the metal cover and the substrate may be poor, which may be difficult to ensure cavity sealing, thereby reducing the reliability and performance consistency of the resonator.

In addition, the stability of the cover above the cavity in the existing technology may also be relatively poor.

### BRIEF SUMMARY OF THE DISCLOSURE

One aspect of the present disclosure provides a film piezoelectric acoustic wave filter. The film piezoelectric acoustic wave filter includes a first substrate; a plurality of acoustic wave resonator units disposed on the first substrate, where each acoustic wave resonator unit includes a piezoelectric induction plate, and a first electrode and a second electrode which are opposite to each other for applying a voltage to the piezoelectric induction plate; and a capping layer on the first substrate, where the capping layer includes a plurality of sub-caps, a sub-cap of the plurality of sub-caps surrounds an acoustic wave resonator unit of the plurality of acoustic wave resonator units to form a first cavity between the acoustic wave resonator unit and the sub-cap, and a separation portion is disposed between adjacent sub-caps to isolate adjacent first cavities.

Another aspect of the present disclosure provides a method for fabricating a film piezoelectric acoustic wave filter. The method includes providing a first substrate; forming a plurality of acoustic wave resonator units on the first substrate, where each acoustic wave resonator unit includes a piezoelectric induction plate, and a first electrode and a second electrode which are opposite to each other for applying a voltage to the piezoelectric induction plate; forming a sacrificial layer on an acoustic wave resonator unit, and adjacent sacrificial layers are separated from each other by a separation space between the adjacent sacrificial layers; forming a capping layer main body to cover the sacrificial layer and fill the separation space; forming a release hole on the capping layer main body, and removing the sacrificial layer through the release hole to form a first cavity; and forming a sealing layer on the capping layer main body to seal the release hole.

Other aspects of the present disclosure can be understood by those skilled in the art in light of the description, the claims, and the drawings of the present disclosure.

### BRIEF DESCRIPTION OF THE DRAWINGS

FIG. 1 illustrates a structural schematic of a film piezoelectric acoustic wave filter according to exemplary embodiment one of the present disclosure;

FIG. 2 illustrates a structural schematic of a film piezoelectric acoustic wave filter according to exemplary embodiment two of the present disclosure;

FIG. 3 illustrates a structural schematic of a film piezoelectric acoustic wave filter according to exemplary embodiment three of the present disclosure;

FIG. 4A illustrates a structural schematic of a film piezoelectric acoustic wave filter according to exemplary embodiment four of the present disclosure;

FIG. 4B illustrates a structural schematic of a film piezoelectric acoustic wave filter according to exemplary embodiment five of the present disclosure; and

FIGS. 5-11 illustrate structural schematics corresponding to certain stages of a method for fabricating a film piezoelectric acoustic wave filter according to exemplary embodiments of the present disclosure.

### DETAILED DESCRIPTION

The present disclosure is further described in detail with reference to the accompanying drawings and specific embodiments hereinafter. The advantages and features of the present disclosure may be more apparent according to the following description and the accompanying drawings. However, it should be noted that the concept of the technical solution of the present disclosure may be implemented in various different forms and may not be limited to specific embodiments set forth herein. The accompanying drawings may be all in simplified forms and non-precise scales and may be merely for convenience and clarity of the purpose of the embodiments of the present disclosure.

It should be understood that when an element or layer is referred to as being “on” “adjacent to”, “connected with”, or “coupled to” other elements or layers, the element or layer may be directly on the other elements or layers, or may be adjacent to, connected, or coupled to other elements or layers; or there may be intermediate elements or layers. In contrast, when an element is referred to as being “directly on”, “directly adjacent to”, “directly connected with”, or “directly coupled to” other elements or layers, there may not be intermediate elements or layers. It should be understood that, although the terms first, second, third and the like may be configured to describe various elements, components, regions, layers and/or sections, these elements, components, regions, layers and/or sections should not be limited by these terms. These terms are only used to distinguish one element, component, region, layer or section from another element, component, region, layer or section. Thus, the first element, component, region, layer or section discussed below could be termed the second element, component, region, layer or section without departing from the scope of the present disclosure.

Spatial relation terms such as “under”, “below”, “beneath”, “above”, “over” and the like may be configured herein for convenience of description to describe the relationship of one element or feature to other elements or features shown in the drawings. It should be understood that spatial relation terms may be intended to include different orientations of the device in use and operation in addition to the orientation shown in the drawings. For example, if the device in the drawings is turned over, then elements or features described as “below” or “beneath” or “under” other elements or features would then be oriented “above” the other elements or features. Thus, exemplary terms “below” and “under” may include both up and down orientations. The device may be otherwise oriented (rotated 90 degrees or at other orientations) and the spatial descriptors used herein may be interpreted accordingly.

The terminology used herein may be for the purpose of describing particular embodiments only and may not be intended to limit the present disclosure. As used herein, the singular forms “a”, “an”, and “the/said” may be intended to include plural forms as well, unless the context clearly dictates otherwise. It should also be understood that terms “contain” and/or “include”, when used in the specification, may be configured to determine the presence of stated features, integers, steps, operations, elements and/or components, but may not exclude one or more other presence or addition of features, integers, steps, operations, elements, parts and/or groups. As used herein, the term “and/or” may include any and all combinations of associated listed items.

If the method described herein includes a series of steps, the step order presented herein may not be necessarily the only order in which the steps may be performed, and some of the steps may be omitted and/or other steps, which are not described herein, may be added to the method. If components in one of the drawings are same as components in other drawings, although the components may be easily recognized in all drawings, in order to make the description of the drawings clearer, labels of all same components may not be marked in each drawing in the present specification.

### Exemplary Embodiment One

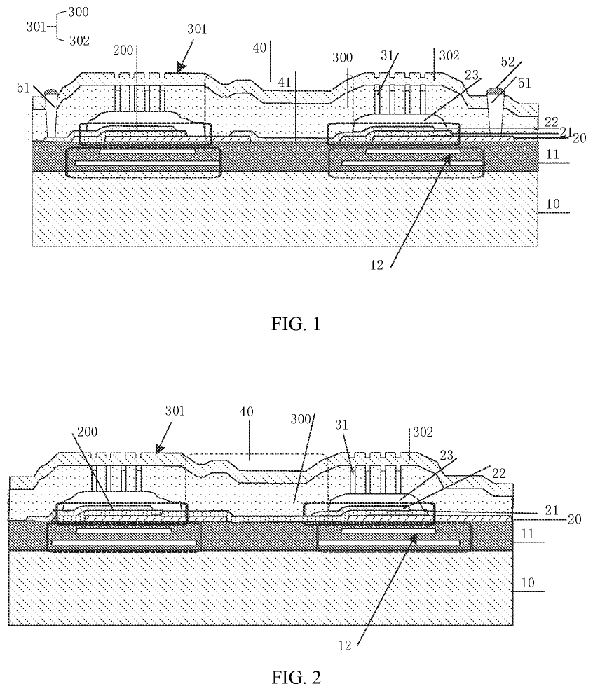

Embodiments of the present disclosure provide a film piezoelectric acoustic wave filter. FIG. 1 illustrates a structural schematic of a film piezoelectric acoustic wave filter according to exemplary embodiment one of the present disclosure. Only two acoustic resonator units may be shown in FIG. 1. For example, the number of acoustic wave resonator units and the electrical connection mode between the acoustic wave resonator units in each filter may be configured according to requirements of the filter itself.

Referring to FIG. 1, the film piezoelectric acoustic wave filter may include a first substrate; and a plurality of acoustic wave resonator units 200 disposed on the first substrate. The acoustic wave resonator unit 200 is the smallest resonance unit, and each acoustic wave resonator unit 200 may include a piezoelectric induction plate 21, and a first electrode and a second electrode which are opposite to each other for applying a voltage to the piezoelectric induction plate 21 (in one embodiment, when the acoustic wave resonator unit 200 is a bulk acoustic wave resonator unit, the first electrode may be an upper electrode 22, and the second electrode may be a lower electrode 20; when the acoustic wave resonator unit is a surface acoustic wave resonator unit, the first electrode and the second electrode may be respectively a first interdigital transducer and a second interdigital transducer on the piezoelectric induction plate). The film piezoelectric acoustic wave filter may further include a capping layer on the first substrate. The capping layer may include a plurality of sub-caps 301, the sub-cap 301 may surround the acoustic wave resonator unit 200 to form a first cavity 23 between the acoustic wave resonator unit 200 and the sub-cap 301, and a separation portion 40 may be disposed between adjacent sub-caps 301 to isolate adjacent first cavities 23.

The separation portion 40 may include side walls of the sub-cap 301, which is shown in one embodiment for illustration.

It should be noted that corresponding relationship between the plurality of acoustic wave resonator units 200 and the plurality of sub-caps 301 in the capping layer may be divided into several types. 1) The plurality of acoustic wave resonator units 200 may be in a one-to-one correspondence with the sub-caps 301, for example, there are 5 acoustic wave resonator units and 5 sub-caps which are in one-to-one correspondence. 2) The number of the acoustic wave resonator units 200 may be greater than the number of the sub-caps 301, some of the acoustic wave resonator units 200 may be in a one-to-one correspondence with the sub-caps 301, and two or more of remaining acoustic wave resonator units may share one first cavity 23. Exemplarily, for example, the number of acoustic wave resonator units is 8, the number of sub-caps 301 is 5, 5 acoustic wave resonator units 200 may be in a one-to-one correspondence with to 5 sub-caps and remaining 3 acoustic wave resonator units 200 may share one sub-cap 301. In such case, the sub-caps 301 in a one-to-one correspondence with the acoustic wave resonator units 200 may be first sub-caps, and the sub-caps 301 which do not have a one-to-one correspondence with the acoustic wave resonator units 200 may be second sub-caps, and the second sub-cap may include at least two acoustic wave resonator units 200.

The first substrate may be configured to support the acoustic wave resonator unit 200. In one embodiment, the first substrate may include a first substrate 10 and a first dielectric layer 11 on the first substrate 10, the first dielectric layer 11 may be disposed with an acoustic wave reflection structure, and the acoustic wave reflection structure may be a second cavity or a Bragg reflection layer. In one embodiment, a Bragg reflection layer 12 may be disposed in the first dielectric layer 11, and the acoustic wave resonator unit 200 may be located in the region surrounded by the Bragg reflection layer 12. When the acoustic wave reflection structure is the second cavity, the edge of the acoustic wave resonator unit 200 may be in the region enclosed by the second cavity.

The plurality of acoustic wave resonator units 200 may be disposed on the first substrate, and the acoustic wave resonator units 200 may be bulk acoustic wave resonator units or surface acoustic wave resonator units. In one embodiment, the acoustic wave resonator unit 200 may be a bulk acoustic wave resonator unit, and the bulk acoustic wave resonator unit may include the lower electrode 20, the piezoelectric induction plate 21 and the upper electrode 22 which are configured to be stacked from bottom to top. The region where the lower electrode 20, the piezoelectric induction plate 21 and the upper electrode 22 overlap each other along the direction perpendicular to the first substrate may be defined as an effective working region. In the present disclosure, along the vertical direction of the piezoelectric induction plate, the upper and lower electrodes may only have oppositely stacked portions in the effective working region; or when the effective working region and the ineffective working region of the piezoelectric induction plate are disconnected with be not connected, the upper and lower electrodes may also have opposite portions in the ineffective working region; and the objective of such configuration may be mainly to prevent shear wave leakage.

The first cavity 23 may be disposed above each of the acoustic resonator units 200, and the first cavity 23 may surround the acoustic resonator unit 200. In one embodiment, the boundary of the first cavity 23 may be located outside the boundary of the effective working region of the acoustic wave resonator unit 200. The boundary of the first cavity 23 may be located outside the boundary of the effective working region of the acoustic wave resonator unit 200, which may be that the boundary of the first cavity 23 may surround the boundary of the effective working region, or two boundaries may be substantially consistent with each other. The substantial consistence may allow two boundaries to have incomplete consistence due to process limitations or process reasons, for example, a margin of 2-5 micrometers may be allowed.

The capping layer may be disposed above and around the first cavity 23, and the capping layer may include a plurality of sub-caps 301, and the sub-caps 301 may cap the first cavity 23. In one embodiment, an SMR (solidly mounted resonator) bulk acoustic wave filter may be configured, and the vacuum degree of the first cavity 23 may be below 10 Torr, for example, between 1 mTorr and 10 Torr. The advantage of such configuration may be that when the acoustic wave propagates to the interface between the upper electrode and high vacuum first cavity, the acoustic wave may have better total reflection, which may be beneficial to desirable performance of the resonator and the filter. In addition, the separation portion 40 may be disposed between the sub-caps 301 of adjacent acoustic wave resonator units 200.

The capping layer may include a capping layer main body 300, having a release hole 31, and a sealing layer 302 sealing the release hole 31. The capping layer main body may be a single-layer film layer or a multi-layer film layer structure, and the material of each film layer may be selected from silicon oxide, silicon nitride, silicon carbide, and an organic solidifying film. In one embodiment, the capping layer main body 300 may be a single-layer film layer. The thickness range of the capping layer main body 300 may be about 5 micrometers to 50 micrometers, and the thickness range of the sealing layer 302 may be about 5 micrometers to 50 micrometers. The thicknesses of the capping layer main body 300 and the sealing layer 302 may complement each other, and the total thickness may be about 10 micrometers to 100 micrometers, which may be flexibly adjusted according to mold resistance requirement. Under a same thickness, the capping layer of such solution may have significantly enhanced mold resistance compared to the capping layer with only the organic solidifying film alone.

The material of the sealing layer 302 may include an inorganic dielectric material or an organic solidifying film. For example, the material of the sealing layer 302 may be silicon dioxide or silicon nitride commonly used in semiconductor technology, and the like. The hole may be sealed with a relatively fast deposition rate. Normal deposition rate may be greater than 10 angstroms per second. The film may start to grow from the sidewall of the release hole 31, and sealing may be finally achieved by thickening of the film layer around the release hole 31. Therefore, the sealing layer may be embedded in the hole. The sealing layer 302 may also be formed by pasting an organic solidifying film, and the film may need to be pasted under vacuum condition. Since the organic solidifying film is relatively soft before solidification, a part of the film layer may be embedded into the hole under vacuum condition to have an embedded effect. The formed sealing layer 302 may be partially embedded in the release hole 31. In such way, in the process of forming the sealing layer 302, the material of the sealing layer 302 may not enter the first cavity 23, which may significantly improve filter performance. In addition, the sealing layer 302 may be partially embedded in the release hole 31, which may also enhance the strength of the capping layer main body 300.

It should be noted that, the lateral dimension of the release hole 31 should not be excessively small or excessively large. If the lateral dimension is excessively small, subsequent removal efficiency of the sacrificial layer may be easily reduced. In the fabrication process, the sacrificial layer may be removed through the release hole 31 to form the first cavity 23, then the sealing layer 302 covering the capping layer main body 300 may be formed, and the sealing layer 302 may seal the release hole 31. If the lateral dimension is excessively large, the sealing layer 302 may be easily filled into the first cavity 23 through the release hole 31, thereby affecting resonator performance; or in order for the sealing layer 302 to only seal the release hole 31, the thickness of the sealing layer 302 may need to be increased accordingly, resulting in an excessively large volume of the resonator. Therefore, in one embodiment, the diameter of the release holes may be 0.01 μm to 5 μm, and the density of the release holes above each of the first cavities 23 may range from 1 to 100 per 100 square micrometers. As an example, the cross-sectional shape of the release hole 31 may be circular, and the lateral dimension of the release hole 31 refers to the diameter of the release hole 31.

The distance from the top surface of the first cavity 23 to the top surface of the acoustic wave resonator unit 200 should not be excessively small or excessively large. During the fabrication process, if the distance is excessively small, the sacrificial layer in the first cavity 23 may not completely cover the top surface of the acoustic wave resonator unit 200. The fabrication process may further include forming the capping layer main body 300 covering the sacrificial layer. If the sacrificial layer cannot completely cover the top surface of the acoustic wave resonator unit 200, the capping layer main body 300 and the top surface of the acoustic wave resonator unit 200 may be in contact with each other accordingly, which may affect the formation of the first cavity 23 and adversely affect resonator performance. If the distance is excessively large, the volume of the resonator may be correspondingly increased, so that the fabrication process of the resonator may be difficult to meet miniaturization development of the device; and the process time required for forming the sacrificial layer and removing the sacrificial layer may increase accordingly, resulting in a waste of process cost and time. Therefore, in one embodiment, the distance from the top surface of the first cavity 23 to the top surface of the acoustic wave resonator unit may be 0.3 micrometer to 10 micrometers.

In the fabrication process, by controlling the thickness of the sacrificial layer, the longitudinal dimension of subsequent first cavity 23 may be controlled, which may simplify the process difficulty of forming the first cavity and have high process flexibility. Moreover, since the sacrificial layer is formed through a semiconductor process, it is beneficial to improve dimensional accuracy of the sacrificial layer, and correspondingly improve dimensional accuracy of the first cavity.

When the acoustic wave resonator unit is working, heat is generated and dissipated through a medium, and the material of the capping layer may be more beneficial for heat dissipation than air. Therefore, disposing the sub-cap 301 on the periphery of each acoustic wave resonator unit 200 may be more beneficial for heat dissipation than that of multiple acoustic wave resonator units 200 sharing one capping layer, thereby improving the life and stability of the filter.

In the present disclosure, between adjacent bulk acoustic wave resonator units 200, the upper electrode or the lower electrode of one of the bulk acoustic wave resonator units 200 may be electrically connected with the upper electrode of another bulk acoustic wave resonator unit 200 or the lower electrode. FIG. 1 shows two adjacent bulk acoustic wave resonator units 200, and electrode interconnection plates 41 may be disposed between adjacent acoustic wave resonator units 200. In one embodiment, the electrode interconnection sheet 41 may connect the upper electrode 22 of one acoustic wave resonator unit 200 with the lower electrode 20 of another acoustic wave resonator unit 200. The electrode interconnection plate 41 may be a conductive material. The materials of the upper electrode 22, the lower electrode 20, and the electrode interconnection plate 41 may include molybdenum, aluminum, tungsten, titanium, copper, nickel, cobalt, thallium, gold, silver, platinum or their alloys; and the materials of the upper electrode 22, the lower electrode 20, and the electrode interconnection plate 41 may be same or different. In other embodiments, two upper electrodes or two lower electrodes of two adjacent acoustic wave resonator units may be connected through the electrode interconnection plate. It should be understood that when the electrode interconnection plate is respectively connected with the upper electrode and the lower electrode of two acoustic wave resonance units, two acoustic wave resonance units may be connected in series; and when the electrode interconnection plate is connected with two upper electrodes or the two lower electrodes simultaneously, two acoustic wave resonance units may be connected in parallel. The electrode interconnection plate may be an integral structure with the upper electrode or the lower electrode, that is, the electrode interconnection plate and the upper electrode or the lower electrode may be formed by patterning a same conductive layer.

In one embodiment, the filter further may include an electrical connection structure, which may be electrically connected with the upper electrode and the lower electrode of the resonator respectively and configured to achieve electrical connection with external circuits.

In one embodiment, the electrical connection structure may include a conductive plug 51, which may pass through the capping layer main body 300 and the sealing layer 302 and may be connected with the upper electrode 22 or the lower electrode 20; and further include a solder ball 52 on the surface of the conductive plug 51.

The material of the conductive plug 51 may include one or more of copper, aluminum, nickel, gold, silver and titanium; and the material of the solder ball 52 may be tin solder, silver solder, or gold-tin alloy solder. In one embodiment, the material of the conductive plug 51 may be copper, and the material of the solder ball 52 may be tin solder.

It should be noted that, in one embodiment, two acoustic wave resonator units 200 may form the filter, which may be configured with an electrical connection structure. In other embodiments, one acoustic wave resonator unit 200 may work alone, and at this point, one single acoustic wave resonator unit may be configured with an independent electrical connection structure. Obviously, the plurality of resonator units 200 may also be connected in parallel or in series to form an integrated structure. At this point, the plurality of resonator units 200 may be jointly configured with an electrical connection structure.

In one embodiment, since the electrodes between adjacent acoustic wave resonator units are connected with each other, there may be a problem of shear wave leakage on the electrodes. The separation portion 40 may change the acoustic impedance of connected electrodes, so that the acoustic impedance of the effective working region may be mismatched with the acoustic impedance of the separation portion, thereby preventing shear wave leakage at the periphery of the first cavity. If the separation portion is located at the boundary of the effective working region, the shear wave leakage problem of the electrode may be better improved.

### Exemplary Embodiment Two

Referring to FIG. 2, the piezoelectric inductive plates 21 of two adjacent piezoelectric resonators may be connected with each other, which is taken as an example in FIG. 2.

In exemplary embodiment two, the piezoelectric induction plates 21 of at least certain adjacent acoustic wave resonator units 200 in the filter may be connected with each other, and a part of the boundary of the projection of the first cavity 23 on the acoustic wave resonator unit 200 may enclose a part of the boundary of the effective working region of the piezoelectric induction plates 21 connected with each other. In one embodiment, the boundary of the effective working region may be an irregular polygon without opposite sides in parallel with each other. When the piezoelectric induction plates 21 of the plurality of acoustic wave resonator units are connected with each other, the region where the upper electrode 22 and the lower electrode 20 of each acoustic wave resonator unit overlap along the direction perpendicular to the piezoelectric induction plate 21 may form the effective working region. The separation portion 40 between adjacent first cavities 23 may make the acoustic impedance mismatch between the effective working region and the ineffective working region, thereby solving the shear wave leakage caused by the connection of the piezoelectric induction plates connected with each other. The upper electrode and the lower electrode of each resonator may be connected with an external circuit through an electrical connection structure, and the specific form of the electrical connection structure refers to exemplary embodiment one, which may not be described in detail herein.

### Exemplary Embodiment Three

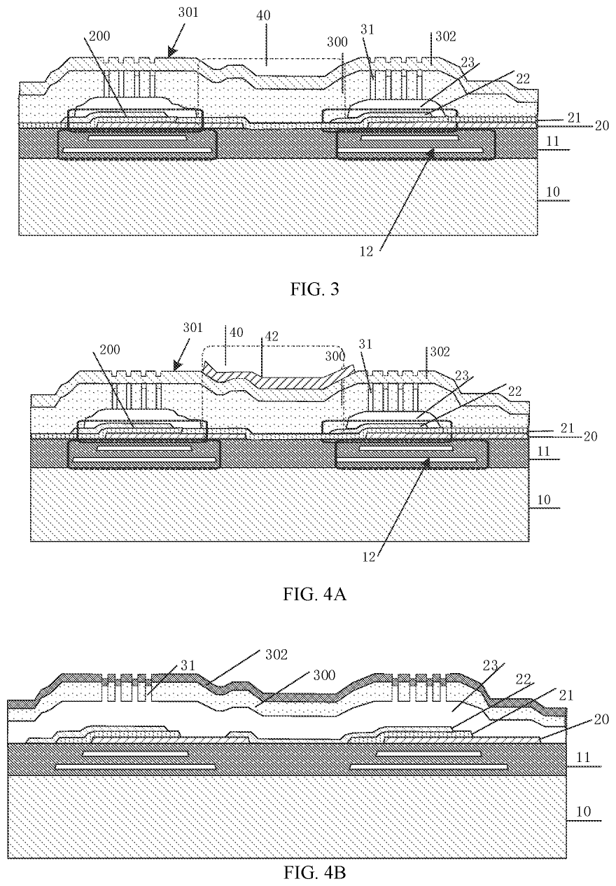

Referring to FIG. 3, in one embodiment, the piezoelectric induction plates 21 of all acoustic wave resonator units 200 in the filter may be connected with each other, and the boundary of the projection of the first cavity 23 on the acoustic wave resonator unit 200 may enclose the boundary of the effective working region of the acoustic wave resonator unit 200. The separation portion 40 between adjacent first cavities 23 may make the acoustic impedance mismatch between the effective working region and the ineffective working region, thereby solving the shear wave leakage caused by the connection of the piezoelectric induction plates 21 connected with each other. In such way, it is not necessary to pattern the piezoelectric layer to form the piezoelectric induction plate of each acoustic wave resonator unit, which may simplify the process. It should be understood that when the overall boundary of the first cavity may coincide with the overall boundary of the effective working region, the size of the first cavity may be the smallest, so that the size of each sub-cap may be reduced, thereby reducing the filter size.

It should be noted that the boundary of the projection of the first cavity 23 on the resonator unit 200 may enclose the boundary of the effective working region of the resonator unit 200, which may indicate that two boundaries may be basically consistent with each other. Certain margin, such as a margin of 2-5 micrometers, may be allowed since two boundaries may be inconsistent due to process limitations. In such way, the boundary of the first cavity 23 may be configured to define the effective working region of the piezoelectric layer, which may effectively prevent shear wave leakage.

The upper electrode and the lower electrode of each resonator may be connected with an external circuit through an electrical connection structure, and the specific form of the electrical connection structure refers to exemplary embodiment one, which may not be described in detail herein.

### Exemplary Embodiment Four

Referring to FIG. 4A, in one embodiment, the separation portion 40 may not only include the sidewalls of the sub-caps 301, but also include a separation film layer 42 formed between adjacent sub-caps 301. The separation film layer 42 may be a newly formed film layer after the capping layer is formed. In such case, the piezoelectric induction plates 21 of adjacent acoustic wave resonator units 200 may be connected with each other, that is, when two piezoelectric induction plates 21 are not disconnected by an etching process and still an integral piezoelectric induction layer, the separation portion 40 may block the shear wave leakage of the piezoelectric induction plates, and the newly formed film layer may strengthen the blocking of shear wave leakage.

The material of the piezoelectric induction plate 21 may include at least one of aluminum nitride, zinc oxide, quartz, lithium niobate, lithium carbonate, and lead zirconate titanate.

### Exemplary Embodiment Five

Referring to FIG. 4B, in one embodiment, at least one sub-cap may surround two or more of the acoustic wave resonance units. The first cavity 23 may accommodate at least two acoustic wave resonance units. The capping layer of the film piezoelectric acoustic wave filter may surround at least two acoustic wave resonator units, and the volume of the first cavity may be relatively large, which may be beneficial to release the sacrificial layer during the fabrication process, improve the process compatibility, and reduce the process difficulty. The plurality of acoustic resonators may share a capping layer, which may increase the flexibility of location selection of the release holes. The plurality of acoustic wave resonator units as a whole may be better realized in series or parallel.

In one embodiment, the sub-cap 301 may include the capping layer main body 300. In another embodiment, the sub-cap 301 may further include the sealing layer 302 and/or the release hole 31, in addition to the capping layer main body 300. In one embodiment, the sealing layer 302 may be made of a material which is same as or different from above-mentioned material, which may not be limited according to various embodiments of the present disclosure.

The sub-cap may have the release hole 31 with a configured diameter, and the sealing layer 302 sealing the release hole 31; and a part of the sealing layer may be embedded in a part of the release hole 31. The pore size of the release holes 31 may range from 0.01 micrometer to 5 micrometers; and the density of the release holes 31 above each first cavity 23 may range from 1 to 100 release holes 31 per 100 square micrometers. The thickness range of the capping layer main body 300 may be 5 micrometers to 50 micrometers, and the thickness range of the sealing layer 302 may be 5 micrometers to 50 micrometers. The thickness of the capping layer main body 300 and the sealing layer may complement each other, and the total thickness may be 10 micrometers to 100 micrometers, which may be flexibly adjusted according to mold resistance requirements. Under a same thickness, the capping layer of such solution may have significantly enhanced mold resistance compared to the capping layer with only the organic solidifying film alone.

The filter may include the plurality of acoustic wave resonator units distributed in at least two of the first cavities. In such way, the volume of the cavity may not be excessively large, the support strength requirement of the capping layer may be balanced, the increase in the height of the cavity and the thickness of the capping layer may be reduced, and the volume of the filter may be desirably controlled.

In the present disclosure, above the acoustic wave resonator unit, independent first cavity may be formed by integral molding of the capping layer, and the plurality of acoustic wave resonance units may be packaged to realize self-encapsulation of the resonance units, so that the packaging process may be convenient and efficient. Compared with the existing technology, the volume of the first cavity may be greatly reduced and required structural strength of the capping layer may be reduced, which may prevent the collapse of the capping layer caused by the cavity.

### Exemplary Embodiment Six

In one embodiment, a method for fabricating the film piezoelectric acoustic wave filter is provided. The method may include following exemplary steps.

At S01, the first substrate may be provided.

At S02, the plurality of acoustic wave resonator units may be formed on the first substrate. Each acoustic wave resonator unit may include the piezoelectric induction plate, and the first electrode and the second electrode which are opposite to each other for applying a voltage to the piezoelectric induction plate.

At S03, the sacrificial layer may be formed on the acoustic wave resonator unit, and adjacent sacrificial layers may be separated from each other by a separation space therebetween.

At S04, the capping layer main body may be formed to cover the sacrificial layer and fill the separation space; and the release hole may be formed on the capping layer main body, and the sacrificial layer may be removed through the release hole to form the first cavity.

At S05, the sealing layer may be formed on the capping layer main body to seal the release hole.

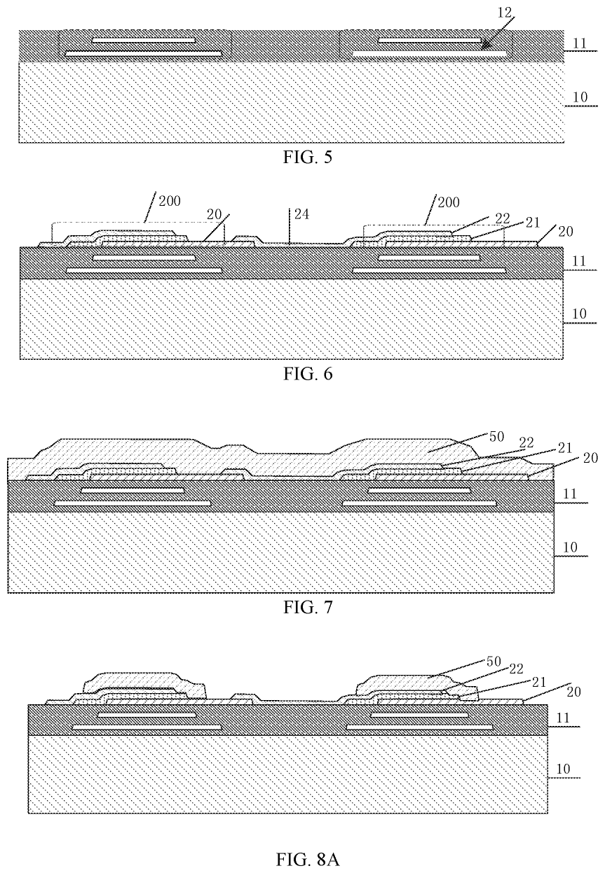

FIGS. 5-11 illustrate structural schematics corresponding to certain stages of a fabrication method of a film piezoelectric acoustic wave filter according to exemplary embodiments of the present disclosure. Referring to FIGS. 5-11, the method for fabricating the film piezoelectric acoustic wave filter is described in detail hereinafter.

Referring to FIG. 5, step S01 that the first substrate may be provided may be performed.

The description about the first substrate may refer to exemplary embodiment one, which may not be described in detail herein.

In one embodiment, the first substrate may include the first substrate 10 and the first dielectric layer 11 on the first substrate 10, and the Bragg acoustic wave reflection layer 12 may be formed in the first dielectric layer 11.

Referring to FIG. 6, step S02, including that the plurality of acoustic wave resonator units may be formed on the first substrate, may be performed. The contents of the arrangement, interconnection, structure and the like of the acoustic wave resonator units 200 refer to relevant contents in exemplary embodiments one, two, three, and four, which may not be described in detail herein. In accompanying drawings, exemplary embodiment one is taken as an example for schematic illustration.

In the method for fabricating the acoustic wave resonator unit in exemplary embodiment one, a conductive film may be formed on the first dielectric layer 11, the conductive film may be patterned to form the lower electrode 20; a piezoelectric film may be formed on the lower electrode 20 and on the first dielectric layer 11 by a vapor deposition process, and the piezoelectric film may be patterned to form the piezoelectric induction plate 21; and a conductive film may be formed on the piezoelectric induction plate 21 and the lower electrode 20, and the conductive film may be patterned to form the upper electrode 22. In one embodiment, the upper electrode 22 and the lower electrode 20 of adjacent acoustic wave resonator units 200 may be connected with each other through a conductive film, so that two acoustic wave resonator units 200 may be connected in series. In other embodiments, two lower electrodes may be connected with each other, or two upper electrodes may be connected with each other, so that two acoustic wave resonator units may be connected in parallel.

In the method of the acoustic wave resonator unit in exemplary embodiment two, a conductive film may be formed on the first dielectric layer 11, the conductive film may be patterned to form the lower electrode 20; and a piezoelectric film may be formed on the lower electrode 20 and on the first dielectric layer 11 by a vapor deposition process, and the piezoelectric film may be patterned to form the piezoelectric induction plate 21. In one embodiment, when the piezoelectric film is patterned, the piezoelectric film that forms the separation portion of the capping layer in the subsequent process may be retained, that is, the piezoelectric induction plates of two adjacent acoustic wave resonator units may be connected with each other. The separation portion between adjacent first cavities formed in the subsequent process may make the acoustic impedance mismatch between the effective working region and the ineffective working region, thereby solving the problem of shear wave leakage caused by the connection of the piezoelectric induction plates.

In the method of the acoustic wave resonator unit in exemplary embodiment three, the difference between this method and above-mentioned method is that after the whole layer of the piezoelectric film is formed, no patterning process may be performed; and the piezoelectric induction plates of all acoustic resonator units may be connected with each other. The separation portion between adjacent first cavities formed in the subsequent process may make the acoustic impedance mismatch between the effective working region and the ineffective working region, thereby solving the shear wave leakage caused by the connection of the piezoelectric induction plates. In addition, it is not necessary to pattern the piezoelectric film to form the piezoelectric induction plate of each resonator unit, which simplifies the process flow and saves the manufacturing cost.

In one embodiment, the method for forming the electrode interconnection plate 24 may include that when forming the upper electrode 22 of one of the acoustic wave resonator units, the conductive material forming the upper electrode may directly form the electrode interconnection plate 24, so that the electrode interconnection plate 24 may be connected with the lower electrode of another acoustic wave resonator unit 200. In one embodiment, the material of the electrode interconnection plate 24 may be same as the material of the upper electrode. In other embodiments, the materials of the upper electrode, the lower electrode, and the electrode interconnection plate may be same or different, but all may be made of conductive materials, such as molybdenum, aluminum, tungsten, titanium, copper, nickel, cobalt, thallium, gold, silver, platinum or their alloys.

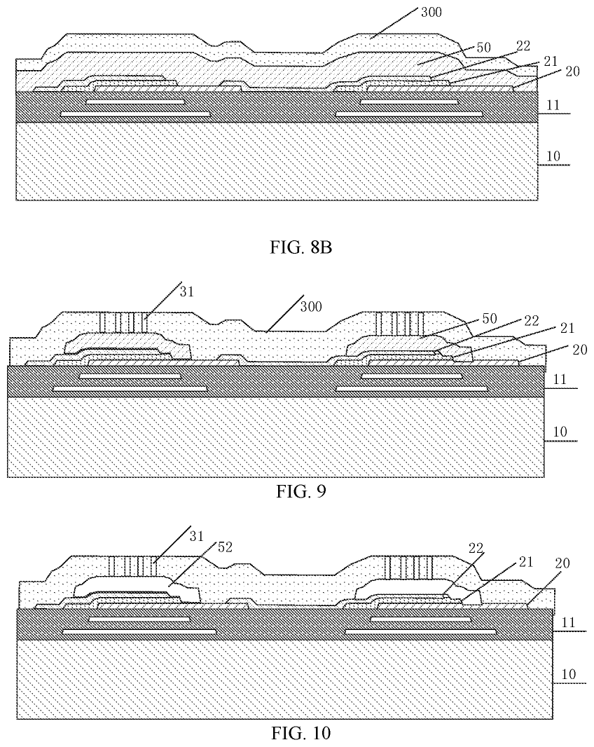

Referring to FIG. 7 and FIG. 8A, step S03, including that the sacrificial layer 50 may be formed on the acoustic wave resonator unit and adjacent sacrificial layers 50 may be separated from each other by the separation space therebetween, may be performed.

The sacrificial layer 50 may be configured to occupy a space for the subsequent formation of the first cavity, that is, the sacrificial layer 50 may be subsequently removed to form the first cavity at the position of the sacrificial layer 50.

The material of the sacrificial layer 50 may be easy to be removed, and the subsequent process of removing the sacrificial layer 50 may have relatively small impact on the first substrate and the acoustic wave resonator unit 200. In addition, the material of the sacrificial layer 50 may ensure that the sacrificial layer 50 has desirable coverage, thereby completely covering the acoustic wave resonator unit 200. For example, the material of the sacrificial layer 50 may include photoresist, polyimide, amorphous carbon, or germanium.

In one embodiment, the material of the sacrificial layer 50 may be photoresist. The photoresist may be a photosensitive material, and patterned by a photolithography process, which may be beneficial to reduce the process complexity of forming the sacrificial layer 50; and the photoresist may be removed by an ashing manner which may be a simple process and have relatively small impact.

For example, forming the sacrificial layer 50 may include forming a sacrificial material layer covering the first substrate and the acoustic wave resonator unit; patterning the sacrificial material layer; and retaining the sacrificial material layer in the acoustic wave resonator unit as the sacrificial layer 50. The sacrificial layers 50 above each acoustic wave resonator unit may be isolated from each other to ensure that the first cavities formed in the subsequent process are isolated from each other.

In other embodiments, as shown in FIG. 8B, when the sacrificial material is patterned, at least a part of the sacrificial layer 50 may cover at least two or more acoustic wave resonator units. In such way, the first cavity formed by the capping in the subsequent stage may accommodate at least two acoustic wave resonator units, and the volume of the first cavity may be relatively large, which may be beneficial to the release of the sacrificial layer during the fabrication process, improve the process compatibility, and reduce the process difficulty. The plurality of acoustic resonators may share a capping layer, which may increase the flexibility of location selection of the release holes. The plurality of acoustic resonator units as a whole may be desirably implemented in series or parallel.

The sacrificial layer 50 may be formed by a semiconductor process. The process of forming the sacrificial layer 50 may be simple, and the process compatibility and process reliability may be high.

In one embodiment, the material of the sacrificial layer 50 may be photoresist, so that the sacrificial material layer may be formed by a coating process, and the sacrificial material layer may be patterned by a photolithography process. In other embodiments, according to the material selected for the sacrificial layer, the sacrificial material layer may also be formed by a deposition process, and the sacrificial material layer may be patterned by a dry etching process.

For example, when the material of the sacrificial layer is polyimide, the sacrificial material layer may be formed by a coating process, and the sacrificial material layer may be patterned by a photolithography process; when the material of the sacrificial layer is amorphous carbon, the sacrificial material layer may be formed by a deposition process, and the sacrificial material layer may be patterned by a dry etching process; and when the material of the sacrificial layer is germanium, the sacrificial material layer may be formed by a deposition process, and the sacrificial material layer may be patterned by a dry etching process.

The thickness of the sacrificial layer may be 0.3 micrometer to 10 micrometers. The reason for selecting such thickness may be referred to above description about the height of the first cavity, which may not be described in detail herein.

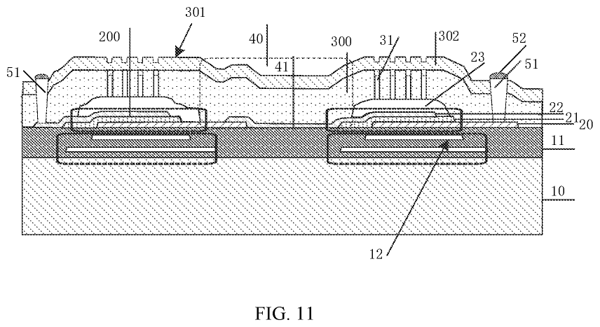

Referring to FIGS. 9-10, step S04, including that the capping layer main body may be formed to cover the sacrificial layer and fill the separation space, the release hole may be formed on the capping layer main body, and the sacrificial layer may be removed through the release hole to form the first cavity, may be performed.

The capping layer main body 300 may be made of a material that is easy to realize patterning, thereby reducing the difficulty of the subsequent process of forming the release holes. Moreover, the capping layer main body 300 may have desirable step coverage, thereby improving the fit between the capping layer main body 300 and the sacrificial layer 50, the first substrate or the ineffective region of the acoustic wave resonator unit. On the one hand, it may be beneficial to ensure the topographical quality and dimensional accuracy of the first cavity; on the other hand, it may make the capping layer main body 300 and the first substrate or the ineffective region of the acoustic wave resonator unit have a high bonding strength. Both of above aspects may be beneficial to improve resonator reliability. Forming the capping layer main body may include forming one or more film layers by a deposition process. The material of each film layer may include silicon oxide, silicon nitride, silicon carbide. Or one or more film layers may be formed by a spin coating process or a lamination process, and the material of each film layer may include an organic solidifying film. The deposition process may include CVD (chemical vapor deposition) and PVD (physical vapor deposition), and the formation method may not be described in detail herein. The thickness range of the capping layer main body 300 may be 5 micrometers to 50 micrometers.

In one embodiment, the material of the capping layer main body 300 may be a photosensitive solidifying material (a type of organic solidifying film), and the capping layer main body 300 may be patterned by a subsequent photolithography process, which may be beneficial to reduce the process complexity and the process precision of the patterning process. For example, the photosensitive solidifying material may be a dry film. The dry film may be a permanent bonding film, and the bonding strength of the dry film may be high, so that the bonding strength of the capping layer main body 300 and the first substrate or the acoustic wave resonator unit may be guaranteed, which may be beneficial to improve the sealing performance of the first cavity.

In one embodiment, the capping layer main body 300 may be formed by a lamination process. The lamination process may be performed in a vacuum environment. By using the lamination process, the step coverage capability of the capping layer main body 300 may be significantly improved, the fit between the capping layer main body 300 and the sacrificial layer 50, the first substrate or the ineffective region of the acoustic wave resonator unit may be improved, and the bonding strength of the capping layer main body 300 and the first substrate or the ineffective region of the acoustic wave resonator unit may be improved.

In other embodiments, a liquid dry film may also be configured to form the capping layer main body, where the liquid dry film refers to that the components in the film-like dry film exist in a liquid form. Correspondingly, forming the capping layer main body may include coating the liquid dry film through a spin coating process; and solidifying the liquid dry film to form the capping layer main body. The solidified liquid dry film may also be a photosensitive material. In other embodiments, the material of the capping layer main body may also be silicon oxide, silicon nitride, silicon carbide, or an organic solidifying film.

The release holes 31 may be configured to provide a process basis for the subsequent removal of the sacrificial layer 50.

The design of the release holes in the capping layer main body may need to consider the release effect of the sacrificial layer and the strength of entire capping layer. The diameter size may range from 0.1 micrometer to 3 micrometers, and the density may range from 1 to 100 per 100 square micrometers. In such way, it may ensure that subsequent capping layer may desirably seal the release hole and may also ensure the release efficiency of the sacrificial layer, and when the capping layer is configured to seal the release hole, it may ensure that the material of the capping layer may not enter the first cavity to affect the performance of the acoustic wave resonator unit.

In one embodiment, the release hole 31 may expose the top surface of the sacrificial layer 50. Compared with the sidewalls of the sacrificial layer 50, the area of the top surface of the sacrificial layer 50 may be relatively large, so that the lateral size and density of the release holes 31 according to process requirement may be easily configured.

In one embodiment, the material of the capping layer main body 300 may be a photosensitive solidifying material (a type of organic solidifying film). Therefore, the capping layer main body 300 may be patterned through a photolithography process to form the release holes 31. By using the photolithography process, the process steps for forming the release holes 31 may be simplified, and the dimensional accuracy of the release holes 31 may be improved.

In other embodiments, when the material of the capping layer main body is a non-photosensitive curing material, a photolithography process including coating photoresist, exposing and developing may be configured to form a photoresist mask; and through the photoresist mask, the capping layer main body may be etched by a dry etching process to form release holes. The dry etching process may have anisotropic etching characteristics, which may be beneficial to improve the topographical quality and dimensional accuracy of the release holes, and the dry etching process may be a plasma dry etching process. Correspondingly, after the release hole is formed, the method may further include removing the photoresist mask through a wet stripping or an ashing process.

Referring to FIG. 11, step S05, including that the capping layer 302 may be formed on the capping layer main body 300 to seal the release hole 31, may be performed.

In one embodiment, the process of forming the sealing layer may be performed in a process chamber with a vacuum degree of 1 mtorr-10 torr. When the sealing layer 302 is formed by the chemical vapor deposition process, the deposition rate may be 10 A/sec-150 A/sec, and the vacuum degree may be 2 torr to 5 torr. When the physical vapor deposition process is used, the deposition rate may be 10 angstroms per second to 20 angstroms per second, and the vacuum degree may be 3 mTorr to 5 mTorr. When the sealing layer 302 is formed by the lamination process, the vacuum degree may be 0.5 torr to 0.8 torr. The material of the sealing layer may include an inorganic dielectric material and an organic solidifying film; and the organic solidifying film may include a dry film.

The sealing layer 302 may realize the encapsulation of the resonator and play the role of sealing and moisture-proof, and correspondingly reduce the influence of the subsequent process on the acoustic wave resonator unit 200, thereby improving the reliability of formed resonator. Moreover, by sealing the first cavity 23, it may be also beneficial to isolate the first cavity 23 from external environment, thereby maintaining the stability of the acoustic performance of the acoustic wave resonator unit 200.

The sealing layer 302 may have desirable covering ability, thereby improving the fit and bonding strength of the sealing layer 302 and the capping layer main body 300 and improving the reliability of the resonator. In one embodiment, the material of the capping layer 302 may be a photosensitive material (a type of organic solidifying film), so that the sealing layer 302 may be patterned by a photolithography process subsequently, which may be beneficial to reduce the process complexity and process precision of the patterning process. For example, the photosensitive material may be a dry film. In other embodiments, the material of the capping layer may also be an inorganic dielectric material.

In one embodiment, the photosensitive material may be a film-like dry film. Correspondingly, the sealing layer 302 may be formed by a lamination process, which may significantly improve the fit and binding strength between the sealing layer 302 and the capping layer main body 300. In other embodiments, according to the material of the sealing layer, the sealing layer may also be formed by a deposition process or a coating process. The description of the sealing layer may refer relevant description of the capping layer main body 300, which may not be described in detail herein.

In one embodiment, the bonding strength between the sealing layer 302 and the capping layer main body 300 may be relatively high, and under the joint action of the sealing layer 302 and the capping layer main body 300, the sealing of the first cavity 23 may be improved, which may correspondingly improve resonator reliability.

The thickness of the capping layer main body may range from 5 micrometers to 50 micrometers, the thickness of the capping layer may range from 5 micrometers to 50 micrometers, the thicknesses of the capping layer main body and the capping layer may complement each other, and the total thickness may be 10 micrometers to 100 micrometers. In an optional solution, the thickness of the capping layer main body may be 20 micrometers to 30 micrometers, and the thickness of the sealing layer may be 5 micrometers to 15 micrometers, which may ensure the structural strength and achieve a desirable sealing effect. In an actual fabrication process, the thickness may be flexibly adjusted according to mold resistance requirements. Under a same thickness, the capping layer of such solution may have significantly enhanced mold resistance compared to the capping layer with only the organic solidifying film alone.

In one embodiment, through the sacrificial layer 50, the capping layer main body 300 and the sealing layer 302, the packaging of the resonator may be realized by the semiconductor process, which may have high process compatibility with the formation process of the acoustic wave resonator unit 200 and correspondingly simplify the process difficulty of forming the first cavity 23. Moreover, the sacrificial layer 50, the capping layer main body 300, the sealing layer 302 and the first cavity 23 may all be formed through a semiconductor process, thereby improving resonator reliability. Since the size of the first cavity is relatively small, the capping layer main body 300 may not need significantly high structural strength and may be relatively thin, so that the thickness of the capping layer may be reduced, and the size of the resonator may be reduced.

In one embodiment, forming the capping layer 302 may further include forming the electrical connection structure. In one embodiment, the electrical connection structure may include the conductive plug 51 and solder ball 52. Forming the electrical connection structure may include forming a through hole passing through the capping layer main body 300 and the sealing layer 302. The through hole may expose the upper electrode or the lower electrode; and the manner for forming the through hole may include a dry etching process. After forming the through hole, the conductive material may be filled in the through hole. The manner for filling the conductive material may include vapor deposition or electroplating; and the conductive material may include one or more of copper, aluminum, nickel, gold, silver, and titanium. After the conductive material is formed, the solder ball 52 may be formed on the top surface of the conductive material through a ball mounting process.

From the above-mentioned embodiments, it can be seen that the technical solutions provided by the present disclosure may achieve at least following beneficial effects.

In the present disclosure, above the acoustic wave resonator unit, independent first cavity may be formed by integral molding of the capping layer, and the plurality of acoustic wave resonance units may be encapsulated to realize self-encapsulation of the resonance units, so that the encapsulation process may be convenient and efficient. Compared with the existing technology, the volume of the first cavity may be greatly reduced and required structural strength of the capping layer may be reduced, which may prevent the collapse of the capping layer caused by the cavity.

Furthermore, each acoustic wave resonator unit may use a cavity, the volume of the first cavity may be further reduced and required structural strength of the capping layer may be further reduced, which may prevent the collapse of the capping layer caused by large cavity.

Furthermore, the isolation portion may be disposed between the sub-caps which are between adjacent acoustic wave resonator units, which may be beneficial to heat dissipation of the acoustic wave resonator units (the heat conduction of the isolation portion is better than the heat conduction of air); and the isolation portion may increase the acoustic impedance mismatch between the effective working region and the ineffective working region of the acoustic wave resonator unit, reduce the leakage loss of the shear acoustic wave, and improve the Q value of the filter.

Furthermore, in the film piezoelectric acoustic wave filter of the present disclosure, the sacrificial layer may be formed, the release hole may be configured to release the sacrificial layer after the capping layer main body is formed, and then the release hole may be sealed with the sealing layer, which may have high process reliability. In addition, the sacrificial layer may cover the acoustic wave resonator unit, and the first cavity formed after releasing the sacrificial layer may correspond to the acoustic wave resonator unit. In such way, the size of the first cavity may be equivalent to the size of the acoustic wave resonator unit, which may greatly reduce the size of the sub-cap compared to the existing technology, so that the strength of the sub-cap may be greatly enhanced.

Furthermore, for the bulk acoustic wave resonator unit, at least a part of the boundary of the projection of the first cavity on the acoustic wave resonator unit may enclose a part of the boundary of the effective working region of the acoustic wave resonator unit, which may be that the boundary of the first cavity may enclose entire boundary of the effective working region. In such way, the size of each sub-cap may be reduced, thereby reducing the size of the filter.

Furthermore, formed capping layer may be partially embedded in the release hole. In such way, in the process of forming the capping layer, the material of the capping layer may not enter the first cavity, which may significantly improve the performance of the filter, and also increase the structural strength of the capping layer main body.

Furthermore, the piezoelectric induction plates of adjacent acoustic resonator units may be connected with each other. The separation portion between adjacent first cavities formed in the subsequent process may make the acoustic impedance mismatch between the effective working region and the ineffective working region, thereby solving the shear wave leakage caused by the connection of the piezoelectric induction plates. In addition, it is not necessary to pattern the piezoelectric film to form the piezoelectric induction plate of each resonator unit, which may simplify the process flow and save the manufacturing cost.

Furthermore, the design of the release holes in the capping layer main body may need to consider the release effect of the sacrificial layer and the strength of entire capping layer. The diameter may range from 0.1 micrometer to 3 micrometers, and the density may range from 1 to 100 per 100 square micrometers. In such way, it may ensure that subsequent capping layer may desirably seal the release hole and may also ensure the release efficiency of the sacrificial layer, and when the capping layer is used to seal the release hole, it may ensure that the material of the capping layer may not enter the first cavity to affect the performance of the acoustic wave resonator unit.

Furthermore, the thickness of the capping layer main body may range from 5 micrometers to 50 micrometers, the thickness of the capping layer may range from 5 micrometers to 50 micrometers, and the thicknesses of the capping layer main body and the capping layer may complement each other. The total thickness may be 10 micrometers to 100 micrometers, which may be flexibly adjusted according to mold resistance requirements. Under a same thickness, the capping layer of such solution may have significantly enhanced mold resistance compared to the capping layer with only the organic solidifying film alone.

Furthermore, the capping layer of the film piezoelectric acoustic wave filter may surround at least two acoustic wave resonator units, and the volume of the first cavity may be relatively large, which may be beneficial to release the sacrificial layer during the fabrication process, improve the process compatibility, and reduce the process difficulty. The plurality of acoustic resonators may share a capping layer, which may increase the flexibility of location selection of the release holes. The plurality of acoustic wave resonator units as a whole may be desirably realized in series or parallel.

Furthermore, the filter may include the plurality of acoustic wave acoustic resonator units, and the plurality of acoustic wave resonator units may be distributed in at least two of the first cavities. In such way, the volume of the cavity may not be excessively large, which may balance the support strength requirement of the capping layer, reduce the increase of the cavity height and the thickness of the capping layer, and may desirably control the volume of the filter.

It should be noted that each embodiment in present specification may be described in a related manner, and same or similar parts between various embodiments may refer to each other. Each embodiment may focus on differences from other embodiments. Particularly, as for structural embodiments, since they are basically similar to method embodiments, the description may be relatively simple, and related parts may refer to partial description of the method embodiments.

Above-mentioned description may be merely for the description of preferred embodiments of the present disclosure and may not be intended to limit the scope of the present disclosure. Any changes and modifications based on above-mentioned embodiments made by those skilled in the art may all be within the scope of the present disclosure.

What is claimed is:

1. A film piezoelectric acoustic wave filter, comprising:
a first substrate;
a plurality of acoustic wave resonator units disposed on the first substrate, wherein each acoustic wave resonator unit includes a piezoelectric induction plate, and a first electrode and a second electrode which are opposite to each other for applying a voltage to the piezoelectric induction plate; and
a capping layer on the first substrate, wherein the capping layer includes a plurality of sub-caps, a sub-cap of the plurality of sub-caps surrounds an acoustic wave resonator unit of the plurality of acoustic wave resonator units to form a first cavity between the acoustic wave resonator unit and the sub-cap, and a separation portion is disposed between adjacent sub-caps to isolate adjacent first cavities.

2. The film piezoelectric acoustic wave filter according to claim 1, wherein:
the acoustic wave resonator unit is a bulk acoustic wave resonator unit, the first electrode is an upper electrode of the piezoelectric induction plate, and the second electrode is a lower electrode of the piezoelectric induction plate; or
the acoustic wave resonator unit is a surface acoustic wave resonator unit, the first electrode and the second electrode are respectively a first interdigital transducer and a second interdigital transducer on the piezoelectric induction plate.

3. The film piezoelectric acoustic wave filter according to claim 1, wherein:
the separation portion includes sidewalls of the sub-cap; or
the separation portion includes sidewalls of the sub-cap and a separation film layer formed between the adjacent sub-caps.

4. The film piezoelectric acoustic wave filter according to claim 1, wherein:
the film piezoelectric acoustic wave filter is a bulk acoustic wave filter; and
at least a part of a boundary of a projection of the first cavity on the acoustic wave resonator unit encloses a part of a boundary of an effective working region of the acoustic wave resonator unit.

5. The film piezoelectric acoustic wave filter according to claim 4, wherein:
piezoelectric induction body plates of a part of adjacent acoustic wave resonator units are connected with each other, and the boundary of the projection of the first cavity encloses a part of the boundary of the effective working region of the piezoelectric induction body plates connected with each other.

6. The film piezoelectric acoustic wave filter according to claim 4, wherein:
piezoelectric induction body plates of all acoustic wave resonator units are connected with each other, and the boundary of the projection of the first cavity encloses the boundary of the effective working region of the acoustic wave resonator unit.

7. The film piezoelectric acoustic wave filter according to claim 4, wherein:
the boundary of the effective working region is an irregular polygon without opposite sides in parallel with each other.

8. The film piezoelectric acoustic wave filter according to claim 2, wherein:
the upper electrode and the lower electrode of the bulk acoustic wave resonator unit are oppositely stacked to each other in the effective working region only; and/or
between adjacent bulk acoustic wave resonator units, an upper electrode or a lower electrode of one of the adjacent bulk acoustic wave resonator units is electrically connected with an upper electrode or a lower electrode of another adjacent bulk acoustic wave resonator unit.

9. The film piezoelectric acoustic wave filter according to claim 1, wherein:
the film piezoelectric acoustic wave filter is an SMR (solidly mounted resonator) bulk acoustic wave filter; and a vacuum degree of the first cavity is between 1 mTorr to 10 Torr.

10. The film piezoelectric acoustic wave filter according to claim 1, wherein:
the capping layer includes a capping layer main body having a release hole, and a sealing layer sealing the release hole;
a part of the sealing layer is embedded in the release hole, wherein the sealing layer is made of a material including an inorganic dielectric material and an organic solidifying film; and
the capping layer main body is a single-layer film layer or a multi-layer film layer structure, and each film layer is made of a material including silicon oxide, silicon nitride, silicon carbide, and an organic solidifying film, wherein:
a thickness of the capping layer main body ranges from about 5 micrometers to about 50 micrometers, and a thickness of the sealing layer ranges from about 5 micrometers to about 50 micrometers.

11. The film piezoelectric acoustic wave filter according to claim 10, wherein:
a diameter of the release hole is about 0.01 micrometer to 5 micrometers; and
a density of release holes above each first cavity ranges from about 1 release hole per 100 square micrometers to about 100 release holes per 100 square micrometers.

12. The film piezoelectric acoustic wave filter according to claim 2, wherein:
the piezoelectric induction plate is made of a material including at least one of aluminum nitride, zinc oxide, quartz, lithium niobate, lithium carbonate, and lead zirconate titanate.

13. The film piezoelectric acoustic wave filter according to claim 1, wherein:
at least one sub-cap surrounds two or more of the plurality of acoustic wave resonance units.

14. The film piezoelectric acoustic wave filter according to claim 13, wherein:
the sub-cap has a release hole with a configured diameter, and a sealing layer that seals the release hole, and a part of the sealing layer is embedded in a part of the release hole, wherein a total thickness of a capping layer main body and the sealing layer is about 10 micrometers to 100 micrometers.

15. The film piezoelectric acoustic wave filter according to claim 13, wherein:
the filter includes the plurality of acoustic wave resonator units disposed in at least two first cavities.

16. A method for fabricating a film piezoelectric acoustic wave filter, comprising:
providing a first substrate;
forming a plurality of acoustic wave resonator units on the first substrate, wherein each acoustic wave resonator unit includes a piezoelectric induction plate, and a first electrode and a second electrode which are opposite to each other for applying a voltage to the piezoelectric induction plate;
forming a sacrificial layer on an acoustic wave resonator unit, and adjacent sacrificial layers are separated from each other by a separation space between the adjacent sacrificial layers;
forming a capping layer main body to cover the sacrificial layer and fill the separation space;
forming a release hole on the capping layer main body, and removing the sacrificial layer through the release hole to form a first cavity; and
forming a sealing layer on the capping layer main body to seal the release hole.

17. The method according to claim 16, wherein:
a process of forming the sealing layer is performed in a process chamber with a vacuum degree of about 1 mtorr to 10 torr; and/or
the sealing layer is formed by a process including a lamination process, a deposition process, or a coating process; and the formed sealing layer is partially embedded in the release hole.

18. The method according to claim 17, wherein:
the sealing layer is formed by the deposition process, and a deposition rate of a deposition material in the deposition process is about 10 angstroms per second to 150 angstroms per second.

19. The method according to claim 16, wherein:
forming the capping layer main body includes forming one or more film layers by a deposition process, wherein each film layer is made of a material including silicon oxide, silicon nitride, silicon carbide; or forming one or more film layers by a spin coating process or a lamination process, wherein each film layer is made of a material including an organic solidifying film.

20. The method according to claim 16, wherein:
the sacrificial layer covers at least two or more of the acoustic wave resonator units.
